(19) United States
(12) Patent Application Publication
(10) Pub. No.: US 2010/0164600 A1
(43) Pub. Date: Jul. 1, 2010

(54) NOVEL CHARGE PUMP

(75) Inventors: CHI KANG LIU, Shanghai (CN); Talee Yu, Shanghai (CN)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Semiconductor Manufacturing International (Shanghai) Corporation, Shanghai (CN)

(21) Appl. No.: 12/616,751

(22) Filed: Nov. 11, 2009

(30) Foreign Application Priority Data
Dec. 31, 2008 (CN) 200810205391.5

(51) Int. Cl. H03K 17/687; G05F 1/10; H01S 4/00

(52) U.S. Cl. 327/437; 327/536; 29/592.1; 327/537

(57) ABSTRACT

A charge pump circuit includes a first voltage supply circuit configured to provide a first supply voltage in response to a first and second input signals. A first capacitor is coupled to the first voltage supply circuit. A first switch circuit is configured to provide a second supply voltage to a second terminal of the first capacitor in response to a first control signal. A second switch circuit is coupled to the second terminal of the first capacitor. A second capacitor is coupled to the second switch circuit. The second switch circuit is configured to cause charge transfer from the first capacitor to the second capacitor in response to a second control signal. The charge pump also includes an output terminal coupled to the second capacitor to provide an output voltage, the output voltage being higher than the first supply voltage, the output voltage being also higher than the second supply voltage.

### CROSS-REFERENCES TO RELATED APPLICATIONS

This application claims priority to Chinese Patent Application No. 200810205391.5, filed Dec. 31, 2008, commonly assigned, incorporated by reference herein for all purposes.

### BACKGROUND OF THE INVENTION

The present invention is directed to integrated circuits and their processing for the manufacture of semiconductor devices. More particularly, the invention provides a method and device for biasing a transistor switch device for the manufacture of integrated circuits. Merely by way of example, the invention has been applied to charge pump circuits for the manufacture of integrated circuits. But it would be recognized that the invention has a much broader range of applicability. For example, the invention can be applied to integrated circuits requiring efficient signal or charge transfer.

Integrated circuits or “ICs” have evolved from a handful of interconnected devices fabricated on a single chip of silicon to millions of devices. Current ICs provide performance and complexity far beyond what was originally imagined. In order to achieve improvements in complexity and circuit density (i.e., the number of devices capable of being packed onto a given chip area), the size of the smallest device feature, also known as the device “geometry”, has become smaller with each generation of ICs. Semiconductor devices are now being fabricated with features less than a quarter of a micron across.

Increasing circuit density has not only improved the complexity and performance of ICs but has also provided lower cost parts to the consumer. An IC fabrication facility can cost hundreds of millions, or even billions, of dollars. Each fabrication facility will have a certain throughput of wafers, and each wafer will have a certain number of ICs on it. Therefore, by making the individual devices of an IC smaller, more devices may be fabricated on each wafer, thus increasing the output of the fabrication facility. Making devices smaller is very challenging, as each process used in IC fabrication has a limit. That is to say, a given process typically only works down to a certain feature size, and then either the process or the device layout needs to be changed. An example of such a limit is the inefficiency in charge pump circuits used for the manufacture of integrated circuits in a cost effective and efficient way.

Fabrication of custom integrated circuits using chip foundry services has evolved over the years. Fabless chip companies often design the custom integrated circuits. Such custom integrated circuits require a set of custom masks commonly called “reticles” to be manufactured. A chip foundry company called Semiconductor International Manufacturing Company (SMIC) of Shanghai, China is an example of a chip company that performs foundry services. Although fabless chip companies and foundry services have increased through the years, many limitations still exist. For example, in high voltage applications such as non-volatile memories, there is often a need for on-chip charge pump circuits. The efficiency of charge pump circuits often is not satisfactory. These and other limitations are described throughout the present specification and more particularly below.

For example, FIG. 1a is a schematic diagram of a circuit used in a conventional charge pump. As shown, circuit 100 includes an MOS transistor 102 connected to a capacitor 104. MOS transistor 102 can be turned on by a control signal and allow charge transfer from input terminal IN to capacitor 104. Circuit 100 may be part of a conventional charge pump circuit. The voltage at source terminal S can be raised by charge build up in capacitor 104. Due to the so-called “body effect” in which the source voltage at node S is raised above the substrate voltage. For example, the threshold voltage of transistor 102 can be raised from 0.6V to 1.3V, causing a substantial drop in output current. As a result, the efficiency of the charge pump circuit can be degraded. From the above, it is seen that an improved technique for charge pump devices is desired.

From the above, it is seen that an improved technique for processing semiconductor devices is desired.

### BRIEF SUMMARY OF THE INVENTION

The present invention is directed to integrated circuits and their processing for the manufacture of semiconductor devices. More particularly, the invention provides a method and device for biasing a transistor switch device for the manufacture of integrated circuits. Merely by way of example, the invention has been applied to charge pump circuits for the manufacture of integrated circuits. But it would be recognized that the invention has a much broader range of applicability. For example, the invention can be applied to integrated circuits requiring efficient signal or charge transfer.

In a specific embodiment, the invention provides a charge pump circuit. The charge pump circuit includes a first voltage supply circuit configured to provide a first supply voltage in response to a first and second input signals. The charge pump circuit includes a first capacitor which includes a first terminal and a second terminal. The first terminal is coupled to the first voltage supply circuit. The charge pump circuit includes a first switch circuit. The first switch circuit provides a second supply voltage to a second terminal of the first capacitor in response to a first control signal. The first switch circuit includes an input terminal, an output terminal, and a substrate terminal wherein the substrate terminal is biased to a higher one of a voltage at the output terminal and a voltage at the input terminal. The charge pump circuit includes a second switch circuit coupled to the second terminal of the first capacitor. The second switch circuit including an input terminal, an output terminal, and a substrate terminal wherein the substrate terminal is biased to a higher one of a voltage at the output terminal and a voltage at the input terminal. The charge pump circuit also includes a second capacitor coupled to the second switch circuit. The second switch circuit causes charge transfer from the first capacitor to the second capacitor in response to a second control signal. The charge pump circuit includes an output terminal coupled to the second capacitor to provide an output voltage. The output voltage is higher than the first supply voltage. The output voltage is also higher than the second supply voltage.

In a specific embodiment, the first switch circuit includes a switch transistor and a bias circuit. The switch transistor includes a gate terminal, a drain terminal, a source terminal, and a substrate terminal. The bias circuit includes a first input terminal coupled to the drain terminal of the switch transistor, a second input terminal coupled to the source terminal of the switch transistor, and an output terminal coupled to the substrate of the switch transistor. The bias circuit provides an output voltage that is the higher one of a voltage at the first input terminal and a voltage at the second input terminal. In an embodiment, the switch transistor in the first switch circuit is a PMOS transistor. In a specific embodiment, the second switch circuit includes a switch transistor and a bias circuit. The switch transistor includes a gate terminal, a drain terminal, a source terminal, and a substrate terminal. The bias circuit includes a first input terminal coupled to the drain terminal of the switch transistor, a second input terminal coupled to the source terminal of switch the transistor, and an output terminal coupled to the substrate of the switch transistor. The bias circuit provides an output voltage that is the higher one of a voltage at the first input terminal and a voltage at the second input terminal. In an embodiment, the switch transistor in the first switch circuit is a NMOS transistor. In an embodiment, the bias circuit includes a first input terminal, a second input terminal, and an output terminal. The bias circuit also includes a first transistor and a second transistor. The first transistor includes a source terminal coupled to the first input terminal, a gate terminal coupled to the second input terminal, and a drain terminal coupled to the output terminal. The second transistor includes a source terminal coupled to the second input terminal, a gate terminal coupled to the first input terminal, and a drain terminal coupled to the output terminal. In an embodiment, the first and second transistors in the bias circuit are PMOS transistors. In an alternative embodiment, the first and second transistors in the bias circuit are NMOS transistors. In a specific embodiment, the first voltage supply circuit includes a PMOS transistor and an NMOS transistor connected in series between the first voltage supply and a third voltage supply, and an output terminal coupled to a drain terminal of the PMOS transistor and a drain terminal of the NMOS transistor. The first voltage supply circuit also includes a first input signal in communication with a gate terminal of the PMOS transistor and a second input signal in communication with a gate terminal of the NMOS transistor. In an embodiment, the third supply voltage is at a ground potential.

An alternative embodiment of the invention provides a device for providing a switching function. The device includes a switch transistor and a bias circuit. The switch transistor includes a gate terminal, a drain terminal, a source terminal, and a substrate terminal. The bias circuit is coupled to the switch transistor and configured to provide a substrate voltage to the substrate terminal. The bias circuit receives a drain voltage from the drain terminal and a source voltage from the source terminal. The bias circuit processes information associated the drain voltage and the source voltage and selects one voltage from the drain voltage and the source voltage. The selected voltage is equal to or higher than both the drain voltage and the source voltage. The bias circuit then outputs the selected voltage as the substrate voltage to the substrate terminal. In a specific embodiment, the bias circuit includes a first input terminal, a second input terminal, and an output terminal. The bias circuit also includes a first transistor and a second transistor. The first transistor includes a source terminal coupled to the first input terminal, a gate terminal coupled to the second input terminal, and a drain terminal coupled to the output terminal. The second transistor includes a source terminal coupled to the second input terminal, a gate terminal coupled to the first input terminal, and drain terminal coupled to the output terminal. In an embodiment, the transistor in the transistor switch device is a PMOS transistor. In an alternative embodiment, the transistor in the transistor switch device is an NMOS transistor. In an embodiment, the first and second transistors are PMOS transistors. In an alternative embodiment, the first and second transistors are NMOS transistors.

In yet another alternative embodiment, the invention provides a method of making a charge pump circuit. The method includes providing a first voltage supply circuit configured to provide a first supply voltage in response to a first and second input signals. The method provides a first capacitor. The method includes coupling a first terminal of the first capacitor to the first voltage supply circuit. The method provides a first switch circuit which is configured to provide a third supply voltage to a second terminal of the first capacitor in response to a first control signal. The first switch circuit including an input terminal, an output terminal, and a substrate terminal wherein the substrate terminal is biased to a higher one of a voltage at the output terminal and a voltage at the input terminal. The method adds a second switch circuit and couples the second switch circuit to the second terminal of the first capacitor. The second switch circuit including an input terminal, an output terminal, and a substrate terminal wherein the substrate terminal is biased to a higher one of a voltage at the output terminal and a voltage at the input terminal. The method adds a second capacitor coupled to the second switch circuit. The second switch circuit supplies a voltage at the second terminal of the first capacitor to the second capacitor in response to a second control signal. The method provides an output terminal coupled to the second capacitor to provide an output voltage which is higher than the first supply voltage. The output voltage is also higher than the second supply voltage. In a specific embodiment, providing a first switch circuit further includes providing a switch transistor and a bias circuit. The transistor includes a gate terminal, a drain terminal, a source terminal, and a substrate terminal. The bias circuit includes a first input terminal, a second input terminal, and an output terminal. The bias circuit provides an output voltage that is the higher of a voltage at the first input terminal and a voltage at the second input terminal. The drain terminal of the switch transistor is coupled to the first input terminal of the bias circuit, the source terminal of the switch transistor is coupled to the second input terminal of the bias circuit, and the substrate of the switch transistor is coupled to the output terminal of the bias circuit.

In yet another embodiment, the invention provides a method for providing an output voltage that is higher than a supply voltage. The method includes providing an input voltage. The method provides a first capacitor, including a first terminal and a second terminal. The method provides a second capacitor. The method charges the second capacitors until an output voltage of the second capacitor reaches a predetermined voltage. The predetermined voltage is higher than the supply voltage. Charging the second capacitor further includes charging the first capacitor to raise a voltage at the second terminal of the first capacitor to the supply voltage, and then decoupling the first capacitor from the supply voltage. The method includes raising a voltage at the first terminal of the first capacitor to the input voltage and causing a voltage at the second terminal of the first capacitor to reach a voltage that is substantially a sum of the supply voltage and the input voltage. The method transfers charges from the first capacitor to the second capacitor, and then decouples the second capacitor from the first capacitor.

In a specific embodiment of the method for providing an output voltage, charging the first capacitor comprises coupling the first terminal of the first capacitor to a ground potential and turning on a first switch device to cause the supply voltage to be coupled to the second terminal of the first capacitor. The first switch device includes a switch transistor coupled to a bias circuit, and the bias circuit biases a substrate terminal of the transistor to a higher one of a drain voltage and a source voltage of the switch transistor. In a specific embodiment, transferring charges from the first capacitor to the second capacitor includes providing a second switch device between the first and second capacitors and turning on the switch device to cause the second terminal of the first capacitor to be coupled to the second capacitor. The second switch device includes a switch transistor coupled to a bias circuit, and the bias circuit is configured to bias the substrate terminal of the switch transistor to a higher one of a drain voltage and a source voltage of the switch transistor. In an embodiment, the bias circuit includes a first input terminal, a second input terminal, an output terminal. The bias circuit also includes a first transistor and a second transistor. The first transistor includes a source terminal coupled to the first input terminal, a gate terminal coupled to the second input terminal, and a drain terminal coupled to the output terminal. The second transistor includes a source terminal coupled to the second input terminal, a gate terminal coupled to the first input terminal, and a drain terminal coupled to the output terminal.

Many benefits are achieved by way of the present invention over conventional techniques. For example, the present technique provides an easy to use process that relies upon conventional technology. In some embodiments, the method provides a method and structure for a transistor switch device having reduced body effect and improved switching efficiency. In certain embodiments, the invention provides charge pump circuits having improved efficiency. Depending upon the embodiment, one or more of these benefits may be achieved. These and other benefits will be described in more throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIG. 1a is a schematic diagram of a circuit used in a conventional charge pump circuit;

FIG. 1b is a schematic diagram of a circuit used in another conventional charge pump circuit;

FIG. 2 is a cross sectional view diagram of a transistor used in a conventional charge pump circuit;

FIG. 3 is a simplified schematic diagram of a charge pump circuit according to an embodiment of the present invention;

FIG. 4 is a simplified schematic diagram of an MOS transistor switch for a charge pump according to an embodiment of the present invention;

FIG. 5 is a simplified drawing showing current-voltage relationship of a charge pump circuit according to an embodiment of the present invention;

FIG. 6 is a simplified flowchart of a method for making a charge pump circuit according to an embodiment of the present invention; and

FIG. 7 is a simplified flowchart of a method for providing a high voltage according to an embodiment of the present invention.

### DETAILED DESCRIPTION OF THE INVENTION

The present invention is directed to integrated circuits and their processing for the manufacture of semiconductor devices. More particularly, the invention provides a method and device for biasing a transistor switch device for the manufacture of integrated circuits. Merely by way of example, the invention has been applied to charge pump circuits for the manufacture of integrated circuits. But it would be recognized that the invention has a much broader range of applicability. For example, the invention can be applied to integrated circuits requiring efficient signal or charge transfer.

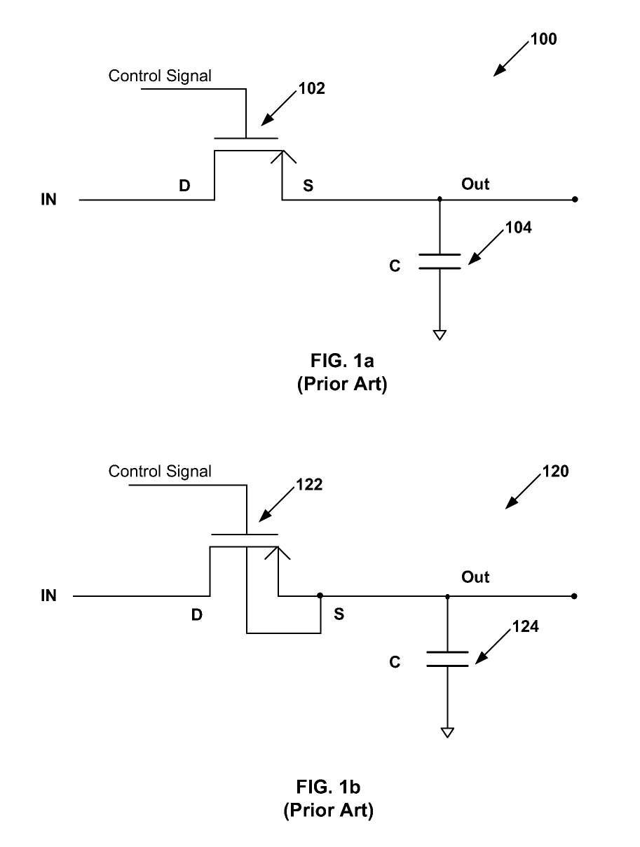

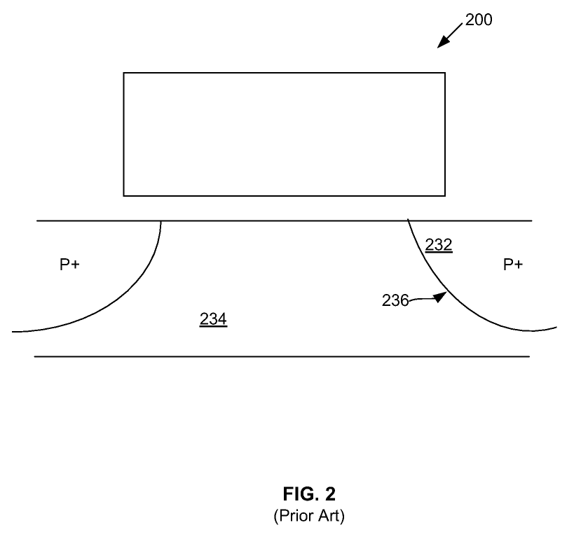

As discussed above, “body effect” in switch transistors can reduce current drive and degrade the efficiency of a charge pump circuit. A solution is illustrated in FIG. 1b, which is a schematic diagram of a circuit used in another conventional charge pump. As shown, circuit 120 includes an MOS transistor 122 with its source terminal S tied to its substrate. This connection can alleviate the problem of “body effect.” However, circuit 120 has its limitations. One of the limitations is shown in FIG. 2. FIG. 2 is a cross sectional view diagram of a transistor 200 used in a conventional charge pump circuit. Under certain charge transfer conditions in a charge pump circuit with power supply voltage Vdd, the P-type drain terminal 232 can be biased at 3*Vdd whereas the N-type substrate 234 is at 2*Vdd. As a result, the drain/substrate junction 236 can become forward biased, causing leakage current and reducing circuit efficiency of the charge pump. These limitations are discussed in more details below.

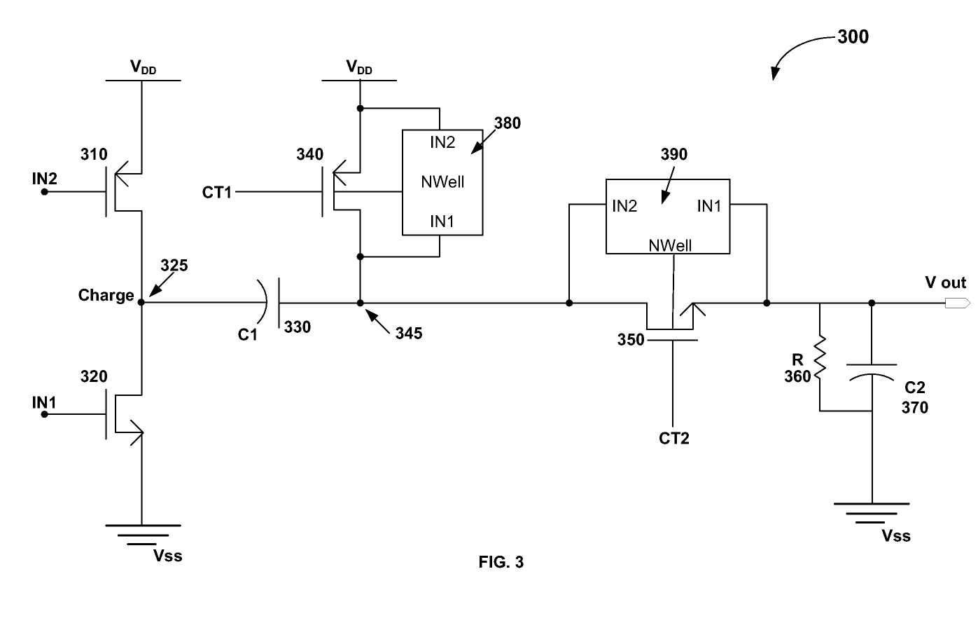

FIG. 3 is a simplified schematic diagram of a charge pump circuit 300 according to an embodiment of the present invention. This diagram is merely an example, which should not unduly limit the scope of the claims herein. One of ordinary skill in the art would recognize many variations, alternatives, and modifications. As shown, charge pump circuit 300 includes capacitors 330 (C1) and 370 (C2) and transistors 310, 320, 340 and 350. In an embodiment, transistors 340 and 350 receive substrate bias voltages from bias circuits 380 and 390, respectively. Although the above has been shown using a selected group of components for the charge pump circuit 300, there can be many alternatives, modifications, and variations. For example, some of the components may be expanded and/or combined. Other components may be inserted to those noted above. Depending upon the embodiment, the arrangement of components may be interchanged with others replaced. Further details of these components are found throughout the present specification and more particularly below.

As shown in FIG. 3, a first terminal of capacitor 330 is coupled to a charge node 325, which is coupled to either a first voltage supply V_{DD} or a second voltage supply Vss, in response to input signals IN1 and IN2. Signal IN1 is coupled to a gate terminal of NMOS transistor 320, whose source terminal is coupled to voltage supply Vss and whose drain terminal is coupled to node 325. Signal IN2 is coupled to a gate terminal of PMOS transistor 310, whose source terminal is coupled to voltage supply V_{DD} and whose drain terminal is coupled to node 325. A second terminal of capacitor 330, labeled 345, is coupled to voltage supply V_{DD} via PMOS transistor 340, in response to signal CT1. Transistor 350, in response to signal CT2, couples node 345 to an output terminal, which is connected to capacitor 370 and resistor 360.

According to a specific embodiment, the charge pump operation of charge pump 300 is now described in more detail. If signals IN1 and IN2 are both low, then NMOS transistor 320 is turned off and PMOS transistor 310 is turned on, pulling node 325 to V_{DD}. Conversely, if signals IN1 and IN2 are both high, NMOS transistor 320 is turned on and PMOS transistor 310 is turned off, pulling node 325 to Vss. In some embodiments, Vss is at a ground potential. In other embodiments, Vss can be set at a different potential depending on the application.

Referring to FIG. 3, if CT1 is low, then PMOS transistor 340 is turned on, pulling node 345 which is coupled to the second terminal of capacitor 330 to V_{DD} according to an embodiment. By coordinating signals IN1, IN2, and CT1, the voltage at node 345 can be raised to reach 2*V_{DD}. For example, by setting IN1 and IN2 high and CT1 low, node 325 is set to Vss, and node 345 is pulled up toward V_{DD}. Capacitor 330 will be charged with electric charges approximately equal to C1* V_{DD}. Next, by setting CT1 high to turn off PMOS transistor 340 and setting IN2 and IN1 low to cause node 325 to be coupled to V_{DD}, node 345 will be at a voltage approximately equal to 2*V_{DD} according to an embodiment. Now, for example, if NMOS transistor 350 is turned on by setting signal CT2 to high, node 345 is coupled to a terminal Vout of capacitor 370. The charges stored in capacitor C1 are now transferred to capacitor C2 to raise a voltage at node Vout. According to certain embodiments, assuming the initial voltage at Vout is V₀, then after the charge transfer Vout is described by the following equation.

Vout=C1/(C1+C2)*(2*C1*V_{DD}+C2*V₀)

By repeating the charging sequence described above, Vout at the output terminal of capacitor C2 can be successively raised to approach a voltage close to 2*V_{DD}.

Referring to charge pump circuit 300 in FIG. 3, transistors 340 and 350 are, for example, switch transistors which allow charge transfer in response to control signals CT1 and CT2, respectively. As discussed above, the performance of charge pump circuit 300 can be affected by the limitations of switch transistors 340 and 350. According to an embodiment of the present invention, charge pump circuit 300 includes bias circuits 380 and 390 to improve the performance of switch transistors 340 and 350. The operation of the bias circuits is now discussed below.

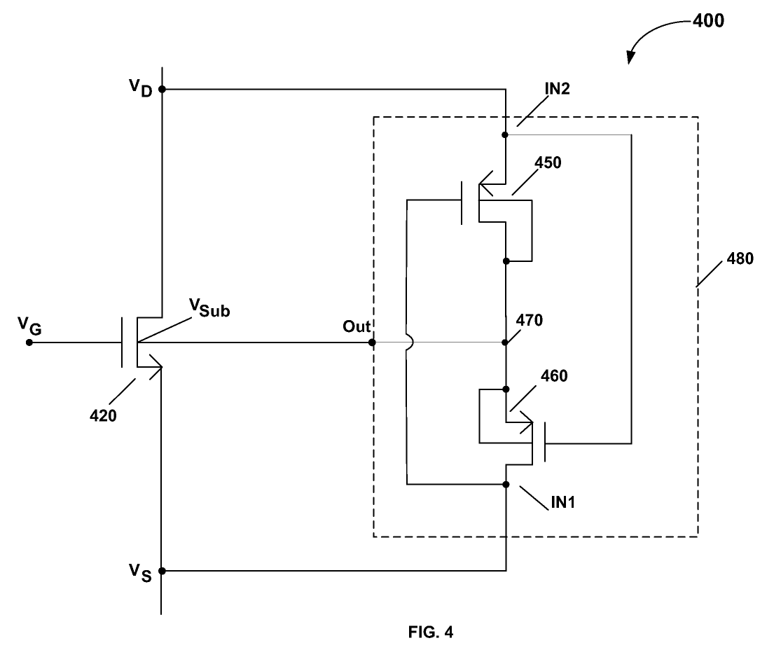

FIG. 4 is a simplified schematic diagram of an MOS transistor switch circuit 400 according to an embodiment of the present invention. This diagram is merely an example, which should not unduly limit the scope of the claims herein. One of ordinary skill in the art would recognize many variations, alternatives, and modifications. As shown, transistor switch circuit 400 includes an NMOS switch transistor 420 coupled to a bias circuit 480. In alternative embodiments, transistor 420 can be a PMOS transistor. Bias circuit 480 includes PMOS bias transistors 450 and 460, input terminals IN1 and IN2, and output terminal OUT. IN1 is connected to a source terminal Vs of transistor 420, and IN2 is connected to a drain terminal V_{D} of transistor 420. OUT terminal of bias circuit 480 provides a bias voltage Vsub to a substrate terminal of transistor 420. Input terminal IN1 is connected to a drain terminal of transistor 460 and a gate terminal of transistor 450. Input terminal IN2 is connected to a source terminal of transistor 450 and a gate terminal of transistor 460. A drain terminal of transistor 450 and a source terminal of transistor 460 are connected to node 470, which is connected to output terminal OUT. In transistor 450, a substrate terminal is connected to a drain terminal. In transistor 460, a substrate terminal is connected to a source terminal. Although the above has been shown using a selected group of components for the switch circuit 400, there can be many alternatives, modifications, and variations. For example, some of the components may be expanded and/or combined. Other components may be inserted to those noted above. Depending upon the embodiment, the arrangement of components may be interchanged with others replaced. Further details of these components are found throughout the present specification and more particularly below.

In a specific embodiment, bias circuit 480 is configured such that Vsub is set to the higher of V_{D} and Vs. Referring to bias circuit 480 in FIG. 4, if the voltage at IN1 is greater than the voltage at IN2, transistor 460 is on and transistor 450 is off. Node 470 and output terminal OUT are pulled toward voltage at IN1. Conversely, if voltage at IN1 is lower than voltage at IN2, transistor 460 is off and transistor 450 is on. Node 470 and output terminal OUT are now pulled toward voltage at IN2. Therefore output terminal OUT of bias circuit 480 is configured to provide a voltage that is the higher of either IN1 or IN2. Therefore, as shown in FIG. 4, a substrate of transistor 420 is biased at the higher voltage of either its drain voltage V_{D} or its source voltage Vs. As a result, bias circuit 480 according to embodiments of the invention is configured to provide a substrate bias to reduce body effect and leakage current in transistor switch circuit 400. Bias circuit 480 can therefore be used in a charge pump to improve its efficiency. Of course, there can be many variations, alternatives, and modifications.

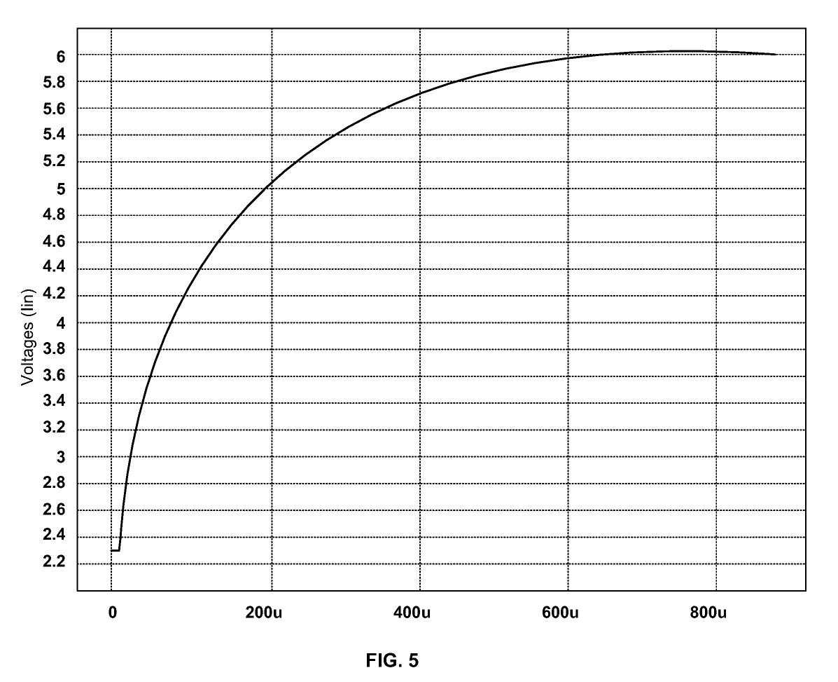

In a specific embodiment, in FIG. 3, bias circuit 380 is used to bias transistor 340, and bias circuit 390 is used to bias transistor 350. Bias circuit 380 provides a substrate bias to transistor 340 that is the higher of its source and drain voltages. This substrate bias reduces body effect and leakage current in transistor 340. Similarly, bias circuit 390 provides a substrate bias to transistor 350 that is the higher of its source and drain voltages. It thereby reduces body effect and leakage current in transistor 350. As a result, improved charge pump performance can be obtained. Of course, there can be many variations, alternatives, and modifications. As a result, improved charge up time and energy efficiency can be obtained with charge pump circuit 300. As an example, FIG. 5 is a simplified I-V diagram showing current-voltage relationship of charge pump circuit 300 according to an embodiment of the present invention. This diagram is merely an example, which should not unduly limit the scope of the claims herein. As shown, according to a specific embodiment of the invention, using a power supply of 3.3 V, charge pump circuit 300 can charge up Vout to 5 volts within 200 usec while supplying 8 mA of current drive to an output load. In comparison, a conventional charge pump circuit using a 3.3 V power supply takes over 200 msec to charge up the output voltage to 5V.

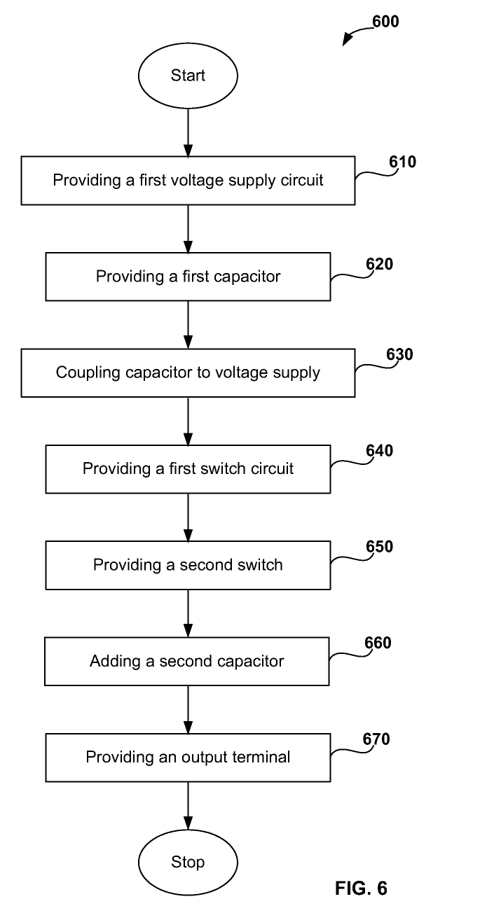

FIG. 6 is a simplified flowchart diagram of a method 600 for making a charge pump circuit according to an embodiment of the present invention. This diagram is merely an example, which should not unduly limit the scope of the claims herein. One of ordinary skill in the art would recognize many variations, alternatives, and modifications.

The method can be briefly outlined below according to some embodiments.
1. Step 610—Providing a first voltage supply circuit, including an output terminal. The voltage supply circuit is configured to provide either a first supply voltage or a second supply voltage at the output terminal in response to a first and second input signals;
2. Step 620—Providing a first capacitor;
3. Step 630—Coupling a first terminal of the first capacitor to the output terminal of the voltage supply circuit;
4. Step 640—Providing a first switch circuit, the first switch circuit being configured to provide a third supply voltage to a second terminal of the first capacitor in response to a first control signal. The first switch circuit includes an input terminal, an output terminal, and a substrate terminal wherein the substrate terminal is biased to a higher one of a voltage at the output terminal and a voltage at the input terminal;
5. Step 650—Providing a second switch circuit including a transfer terminal. The second switch circuit is configured to supply a voltage at the second terminal of the first capacitor to the transfer terminal in response to a second control signal. The second switch circuit including an input terminal, an output terminal, and a substrate terminal wherein the substrate terminal is biased to a higher one of a voltage at the output terminal and a voltage at the input terminal;
6. Step 660—Adding a second capacitor, coupled to the transfer output terminal of the second switch circuit, and
7. Step 670—Providing an output terminal coupled to the second capacitor to provide an output voltage to a load device.

The above sequence of steps provides a method for making a charge pump circuit according to an embodiment of the present invention. As shown, the method uses a combination of steps including a way of using a bias circuit to reduce body effect in a switch circuit according to embodiments of the present invention. Other alternatives can also be provided where steps are added, one or more steps are removed, or one or more steps are provided in a different sequence without departing from the scope of the claims herein.

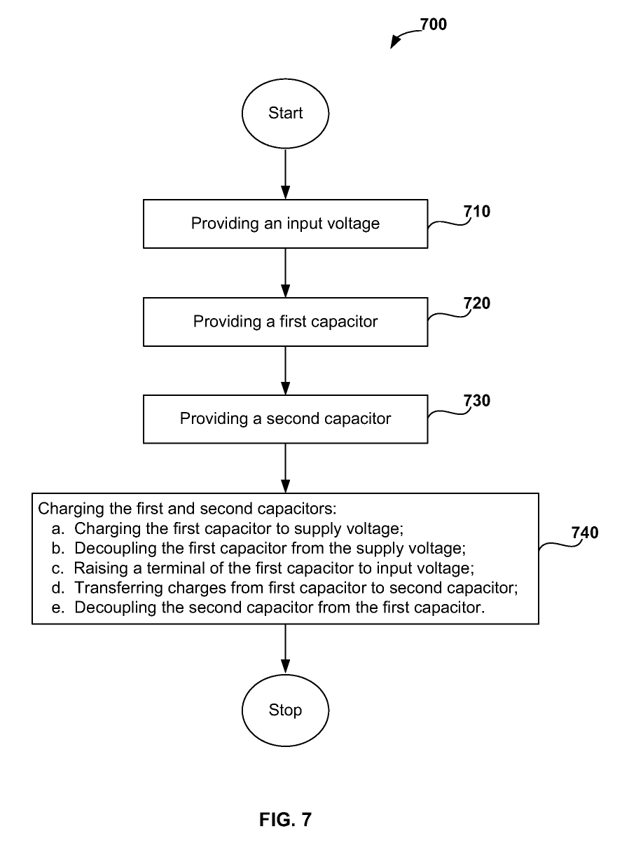

FIG. 7 is a simplified flowchart diagram of a method 700 for providing a high voltage according to an embodiment of the present invention. This diagram is merely an example, which should not unduly limit the scope of the claims herein. One of ordinary skill in the art would recognize many variations, alternatives, and modifications.

The method can be outlined below according to certain embodiments.
1. Step 710—providing an input voltage;
2. Step 720—providing a first capacitor, the first capacitor having a first terminal and a second terminal;
3. Step 730—providing a second capacitor; and
4. Step 740—charging the first and second capacitors until a predetermined output voltage is reached at the second capacitor, where the charging of the first and second capacitors includes the following steps:
   a. charging the first capacitor to raise a voltage at the second terminal to the supply voltage,
   b. decoupling the first capacitor from the supply voltage;
   c. raising a voltage at the first terminal of the first capacitor to the input voltage and causing a voltage at the second terminal to reach substantially a sum of the supply voltage and the input voltage;
   d. transferring charges of the first capacitor to the second capacitor; and
   e. decoupling the second capacitor from the first capacitor.

The above sequence of steps provides a method for generating a high voltage according to an embodiment of the present invention. As shown, the method uses a combination of steps including a way of using a bias circuit to reduce body effect in a switch circuit according to embodiments of the present invention. Other alternatives can also be provided where steps are added, one or more steps are removed, or one or more steps are provided in a different sequence without departing from the scope of the claims herein.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A charge pump circuit comprising:
a first voltage supply circuit, the first voltage supply circuit being configured to provide a first supply voltage in response to a first and second input signals;
a first capacitor, including a first terminal and a second terminal, the first terminal being coupled to the first voltage supply circuit;
a first switch circuit, the first switch circuit being configured to provide a second supply voltage to the second terminal of the first capacitor in response to a first control signal, the first switch circuit including an input terminal, an output terminal, and a substrate terminal wherein the substrate terminal is biased to a higher one of a voltage at the output terminal and a voltage at the input terminal;
a second switch circuit, the second switch circuit being coupled to the second terminal of the first capacitor, the second switch circuit including an input terminal, an output terminal, and a substrate terminal wherein the substrate terminal is biased to a higher one of a voltage at the output terminal and a voltage at the input terminal;
a second capacitor coupled to the second switch circuit, the second switch circuit being configured to cause charge transfer from the first capacitor to the second capacitor in response to a second control signal; and
an output terminal coupled to the second capacitor to provide an output voltage, the output voltage being higher than the first supply voltage, the output voltage being also higher than the second supply voltage.

2. The charge pump circuit of claim 1, wherein the first switch circuit further comprises:
a switch transistor, the switch transistor including a gate terminal, a drain terminal, a source terminal, and a substrate terminal; and
a bias circuit, the bias circuit comprising:
a first input terminal coupled to the drain terminal of the switch transistor;
a second input terminal coupled to the source terminal of the switch transistor; and
an output terminal coupled to the substrate of the switch transistor;
wherein the bias circuit is configured to provide an output voltage that is the higher one of a voltage at the first input terminal and a voltage at the second input terminal.

3. The charge pump circuit of claim 2, wherein the switch transistor in the first switch circuit is a PMOS transistor.

4. The charge pump circuit of claim 2, wherein the bias circuit comprises:
a first input terminal;
a second input terminal;
an output terminal;
a first bias transistor, including a source terminal coupled to the first input terminal, a gate terminal coupled to the second input terminal, and a drain terminal coupled to the output terminal; and
a second bias transistor, including a source terminal coupled to the second input terminal, a gate terminal coupled to the first input terminal, and a drain terminal coupled to the output terminal.

5. The charge pump circuit of claims 4, wherein the first and second bias transistors in the bias circuit are PMOS transistors.

6. The charge pump circuit of claim 4, wherein the switch transistor in the second switch circuit is an NMOS transistor.

7. The charge pump circuit of claim 1, wherein the second switch circuit further comprises:
a switch transistor, the switch transistor including a gate terminal, a drain terminal, a source terminal, and a substrate terminal; and
a bias circuit, the bias circuit comprising:
a first input terminal coupled to the drain terminal of the transistor;
a second input terminal coupled to the source terminal of the transistor; and
an output terminal coupled to the substrate of the transistor;
wherein the bias circuit is configured to provide an output voltage that is the higher one of a voltage at the first input terminal and a voltage at the second input terminal.

8. The charge pump circuit of claims 7, wherein the first and second bias transistors in the bias circuit are NMOS transistors

9. The charge pump circuit of claim 1, wherein the first voltage supply circuit comprises:
a PMOS transistor and an NMOS transistor connected in series between the first voltage supply and a third voltage supply;
an output terminal, coupled to a drain terminal of the PMOS transistor and a drain terminal of the NMOS transistor;
the first input signal being in communication with a gate terminal of the PMOS transistor; and
the second input signal being in communication with a gate terminal of the NMOS transistor.

10. The charge pump circuit of claim 9, wherein the third supply voltage is at a ground potential.

11. A device for providing a switching function, the device comprising:
a switch transistor including a gate terminal, a drain terminal, a source terminal, and a substrate terminal; and
a bias circuit coupled to the switch transistor and configured to provide a substrate voltage to the substrate terminal;
wherein the bias circuit is further configured to:
receive a drain voltage from the drain terminal;
receive a source voltage from the source terminal;
process information associated the drain voltage and the source voltage;
select one voltage from the drain voltage and the source voltage, the selected voltage being equal to or higher than both the drain voltage and the source voltage; and
output the selected voltage as the substrate voltage to the substrate terminal.

12. The device of claim 11, wherein the bias circuit comprises:
a first input terminal;
a second input terminal;
an output terminal;
a first bias transistor, including a source terminal coupled to the first input terminal, a gate terminal coupled to the second input terminal, and a drain terminal coupled to the output terminal; and
a second bias transistor, including a source terminal coupled to the second input terminal, a gate terminal coupled to the first input terminal, and drain terminal coupled to the output terminal.

13. The device of claim 11, wherein the switch transistor (no antecedent) is a PMOS transistor.

14. The device of claim 11, wherein the switch transistor (no antecedent) is an NMOS transistor.

15. The device of claim 12, wherein the first and second bias transistors are PMOS transistors.

16. The device of claim 12, wherein the first and second bias transistors are NMOS transistors.

17. A method of making a charge pump circuit, the method comprising:
providing a first voltage supply circuit, the first voltage supply circuit being configured to provide a first supply voltage in response to a first and second input signals;
providing a first capacitor;
coupling a first terminal of the first capacitor to the first voltage supply circuit;
providing a first switch circuit, the first switch circuit being configured to provide a third supply voltage to a second terminal of the first capacitor in response to a first control signal, the first switch circuit including an input terminal, an output terminal, and a substrate terminal wherein the substrate terminal is biased to a higher one of a voltage at the output terminal and a voltage at the input terminal;
providing a second switch circuit, the second switch circuit including an input terminal, an output terminal, and a substrate terminal wherein the substrate terminal is biased to a higher one of a voltage at the output terminal and a voltage at the input terminal;
coupling the second switch circuit to the second terminal of the first capacitor;
adding a second capacitor coupled to the second switch circuit, the second switch circuit being configured to supply a voltage at the second terminal of the first capacitor to the second capacitor in response to a second control signal; and
providing an output terminal coupled to the second capacitor to provide an output voltage, the output voltage being higher than the first supply voltage, the output voltage being also higher than the second supply voltage.

18. The method of claim 17, wherein providing a first switch circuit further comprises:
providing a switch transistor, the transistor having a gate terminal, a drain terminal, a source terminal, and a substrate terminal; and
providing a bias circuit, the bias circuit having a first input terminal, a second input terminal, and an output terminal, the bias circuit being configured to provide an output voltage that is the higher of a voltage at the first input terminal and a voltage at the second input terminal;
wherein the drain terminal of the switch transistor is coupled to the first input terminal of the bias circuit, the source terminal of the switch transistor is coupled to the second input terminal of the bias circuit, and the substrate of the transistor is coupled to the output terminal of the bias circuit.

19. A method for providing an output voltage higher than a supply voltage, the method comprising:
providing an input voltage;
providing a first capacitor, the first capacitor including a first terminal and a second terminal;
providing a second capacitor; and
charging the second capacitor until an output voltage of the second capacitor reaches a predetermined voltage, the predetermined voltage being higher than the supply voltage, wherein charging the second capacitor comprises:
charging the first capacitor to raise a voltage at the second terminal of the first capacitor to the supply voltage;
decoupling the first capacitor from the supply voltage;
raising a voltage at the first terminal of the first capacitor to the input voltage and causing a voltage at the second terminal of the first capacitor to reach a voltage that is substantially a sum of the supply voltage and the input voltage;
transferring charges from the first capacitor to the second capacitor; and
decoupling the second capacitor from the first capacitor.

20. The method of claim 19, wherein charging the first capacitor comprises:
coupling the first terminal of the first capacitor to a ground potential; and
turning on a first switch device to cause the supply voltage to be coupled to the second terminal of the first capacitor, wherein the first switch device includes a switch transistor coupled to a bias circuit, the bias circuit being configured to bias a substrate terminal of the transistor to a higher one of a drain voltage and a source voltage of the transistor.

21. The method of claim 20, wherein the bias circuit comprises:
a first input terminal;
a second input terminal;
an output terminal;
a first bias transistor, including a source terminal coupled to the first input terminal, a gate terminal coupled to the second input terminal, and a drain terminal coupled to the output terminal; and
a second bias transistor, including a source terminal coupled to the second input terminal, a gate terminal coupled to the first input terminal, and a drain terminal coupled to the output terminal.

22. The method of claim 19, wherein transferring charges from the first capacitor to the second capacitor comprises:
providing a second switch device between the first and second capacitors; and
turning on the second switch device to cause the second terminal of the first capacitor to be coupled to the second capacitor, wherein the second switch device includes a switch transistor coupled to a bias circuit, the bias circuit being configured to bias the substrate terminal of the switch transistor to a higher one of a drain voltage and a source voltage of the switch transistor.
